(19) United States
(12) Patent Application Publication
(10) Pub. No.: US 2016/0126108 A1
(43) Pub. Date: May 5, 2016

(54) METHOD OF REDUCING GATE LEAKAGE IN A MOS DEVICE BY IMPLANTING GATE LEAKAGE REDUCING SPECIES INTO THE EDGE OF THE GATE

(71) Applicant: Texas Instruments Incorporated, Dallas, TX (US)

(72) Inventor: Ebenezer Eshun, Frisco, TX (US)

(21) Appl. No.: 14/531,308

(22) Filed: Nov. 3, 2014

(51) Int. Cl. H01L 21/3115; H01L 29/51; H01L 21/28; H01L 21/265

(52) U.S. Cl. CPC H01L 21/31155; H01L 21/26586; H01L 29/51; H01L 21/28176; H01L 21/28185

(57) ABSTRACT

In a MOS device, gate leakage is reduced by implanting gate oxide leakage reduction species such as nitrogen into the gate oxide along the edges of the gate to reduce gate leakage and hence reduce data retention fails in SRAM devices and allow low Vdd SRAM operation without increasing gate oxide thickness. By implanting nitrogen along the edges of the gate it simultaneously replaces lost gate oxide nitrogen to further reduce gate leakage.

### FIELD OF THE INVENTION

The invention relates to the fabrication of semiconductor devices. In particular it relates to MOS devices and reducing gate leakage. More particularly it relates to the fabrication of SRAM devices and reducing gate leakage without increasing gate oxide thickness to improve data retention that allows low power memory technology.

### BACKGROUND OF THE INVENTION

A conventional SRAM cell consists of six transistors. Such SRAM cell is also referred as a six-transistor static random access memory (6T SRAM).

Referring to FIG. 1, a schematic circuit diagram of a conventional 6T SRAM cell is illustrated, The 6T SRAM cell comprises a flip-flop and two access transistors. The flip-flop includes a pair of cross-coupling inverters. The first inverter includes a first NMOS transistor 100 and a first PMOS transistor 120. The source electrode of the PMOS transistor 120 is connected to a power source voltage Vcc. The drain electrode of the PMOS transistor 120 is connected to the drain of the NMOS transistor 100 and defines the output terminal of the first inverter. The gate electrode of the PMOS transistor 120 is connected to the gate electrode of the NMOS transistor 100 and defines the input terminal of the first inverter. The source electrode of the first NMOS transistor 100 is connected to a ground terminal. The second inverter includes a second NMOS transistor 110 and a second PMOS transistor 130. The source electrode of the second PMOS transistor 130 is connected to the power source voltage Vcc. The drain electrode of the second PMOS transistor 130 is connected to the drain of the second NMOS transistor 110 and defines the output terminal of the second inverter. The gate electrode of the second PMOS transistor 130 is connected to the gate of the second NMOS 110 and defines the input terminal of the second inverter. The source electrode of the second NMOS transistor 110 is connected to the ground terminal. The outputs and inputs to the two inverters are cross coupled as shown in FIG. 1.

The first access transistor 140 is interconnected between the output terminal of the first inverter and the input terminal of the second inverter, and to a bit line BL. The second access transistor 150 is interconnected between the output terminal of the second inverter and the input terminal of the first inverter, and to an inverted bit line (/BL). That is, the first access transistor 140 and the second access transistor 150 are switch elements controllable by the word line (WL) signal. The first access transistor 140 and the second access transistor 150 are also referred as the pass-gate transistors.

Furthermore, the bit line BL and the inverted bit line (/BL) are both connected to a sense amplifier (not shown). When the first access transistor 140 and the second access transistor 150 are turned on in response to the word line signal, the signals of the bit line BL and the inverted bit line (/BL) are outputted from the SRAM through the sense amplifier (not shown).

Consider the PMOS transistors 120 and 130, an example of which is shown in cross-section in FIG. 2. The PMOS transistor includes a drain 200 and source 210 formed on either side of a channel 220. Charge storage nodes are formed by the capacitors defined between the drain 200 and the channel 220, and between the gate 240 and the channel 220 of the PMOS transistors as shown in the sectional prior art view of FIG. 2.

As shown in FIG. 2, one form of charge leakage takes place as sub-threshold leakage 250 due to shorter channel lengths, higher channel doping and threshold voltage Vt not scaling as fast as Vdd. Another form of charge leakage is gate oxide leakage (Ioffg) 260. As the gate oxide thins, this gate oxide leakage increases exponentially. A third form of charge leakage, referred to as gate induced diode leakage (GIDL) 270 results in band to band tunneling and can be ascribed to shallow junctions and high doping of the drain 200 and source 210.

As shown in FIG. 2, Boron pockets 212 are commonly implanted into the channel for adjusting the threshold voltage Vt. In order to suppress boron penetration into the gate oxide, one prior art solution is to add nitrogen to the gate oxide deposition process or implanting nitrogen through the gate electrode at high energy on the order of 40 keV.

### SUMMARY OF THE INVENTION

The present invention, among other things, seeks to reduce SRAM data retention problems. According to the invention, SRAM data retention fails are reduced by reducing gate edge gate leakage. More generally, the present invention reduces gate leakage without increasing gate oxide thickness. According to the invention gate leakage in a MOS transistor is reduced by implanting species along the gate edges to break up any leakage paths in the gate oxide along the gate edges that may have been induced from post processing after the gate oxide process. An example of such species is nitrogen that is implanted as pockets into the gate oxide along the edges of the gate at an implant angle of 20 to 30 degrees (measured from the vertical). The benefit of using nitrogen is that it also helps to fill any lost nitrogen in the gate oxide that was originally added during the gate oxide process in order to suppress boron penetration into the gate oxide. The implant angle of the gate leakage reduction species is the same as the implant angle of the threshold adjustment pockets. The gate leakage reduction species dosage may range from 1e14 to 1e15, preferably between 2e14 and 8e14, more preferably at 6e14. The implant energy may range from 1 keV to 10 keV, preferably from 1 keV to 6 keV, more preferably at 2 keV.

Further, according to the invention, there is provided a method of reducing gate leakage in a MOS transistor, comprising implanting nitrogen in the gate oxide along the gate edge to replace lost nitrogen that was included in the gate oxide during growth.

Still further, according to the invention, there is provided a MOS transistor that includes a gate oxide and a gate located over the gate oxide, comprising a gate oxide leakage reduction species configured to define pockets extending along edges of the gate. The gate oxide leakage reduction species pockets may comprise nitrogen pockets.

Still further, according to the invention, there is provided a method of providing a low power SRAM device, comprising implanting oxide leakage reduction species such as nitrogen pockets into the gate oxide along the gate edges of MOS storage transistors used in the SRAM device.

### BRIEF DESCRIPTION OF THE DRAWINGS

FIG. 1 is a schematic circuit diagram of a typical 6T SRAM device as known in the art;

FIG. 2 is a sectional view through a MOS device as known in the art;

FIG. 3 is a sectional view through a MOS device usable for instance in an SRAM in accordance to one embodiment of the invention, and

FIG. 4 is a top view of the MOS device of FIG. 3.

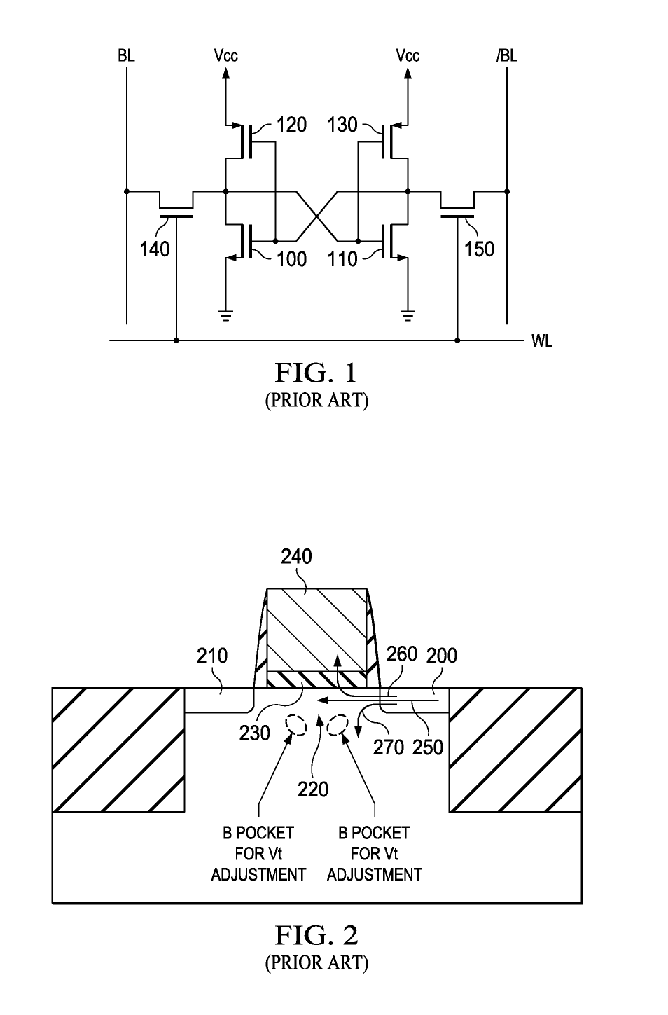

### DETAILED DESCRIPTION OF THE INVENTION

Consider again the sectional view of a prior art MOS device shown in FIG. 2. The p+ regions of the drain 200 and source 210 are theoretically isolated from each other by an n-channel 220 and the gate oxide 230 of gate 240. Nevertheless, due to gate edge defects in the gate oxide 230, charge leakage will occur if there is a complete line of defects across the edge of the gate oxide 230 extending from the bottom of the gate 240 to the top of the channel 220.

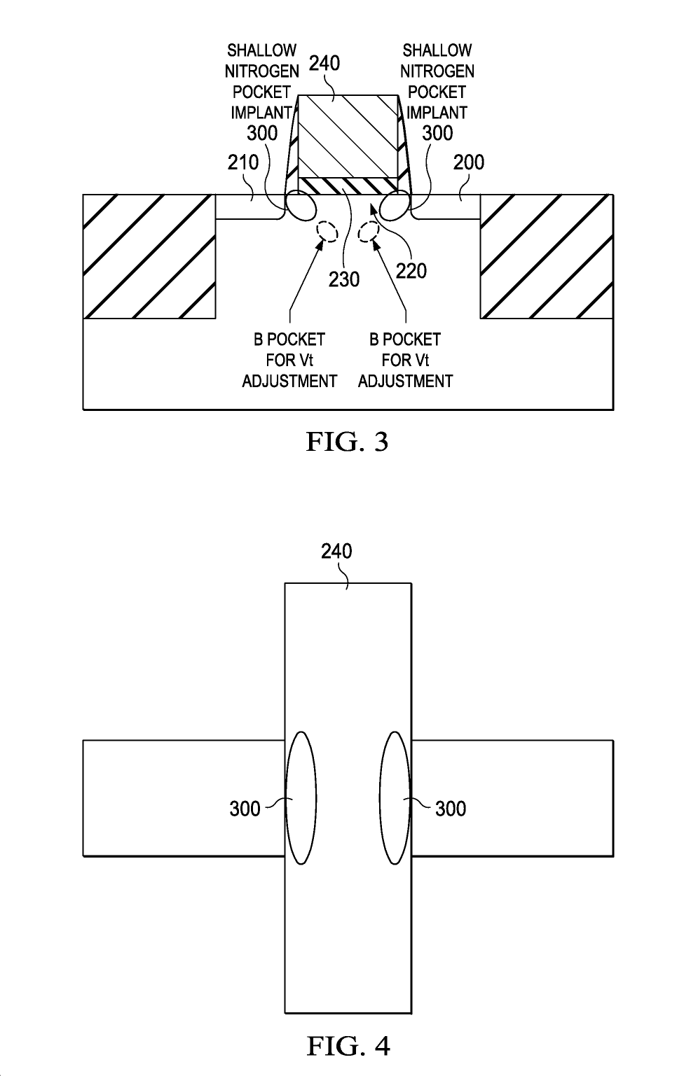

One embodiment of the invention will now be discussed with respect to FIG. 3, and the top view shown in FIG. 4. For ease of reference the same reference numerals will be used to depict similar structural as those in FIG. 2. Pockets 300 of a gate leakage reduction species such as nitrogen are implanted at an angle along edges of the gate 240 to place the nitrogen pockets in the gate oxide 230 along the edge of the gate 240, the angle being substantially the same as that used for any boron pocket 250 implants used for threshold adjustment. The nitrogen implants in this embodiment make use of the same masks as used for the boron implants. In this embodiment the nitrogen implant is performed prior to the boron implant and is done after the first sidewall spacer has been formed. It will be understood that the sidewall spacer may comprise a double or triple sidewall spacer. The exact size and configuration of the nitrogen implants may vary provided that the nitrogen pocket is located along the edge of the gate oxide, between the gate oxide and the silicon of the underlying channel region. As shown in FIG. 4, the gate leakage reduction pockets, e.g., nitrogen pockets, extend at least along the gate edges adjacent the active regions to prevent leakage between the bottom of the gate and the channel region. The implant angle of the nitrogen pockets 300 is chosen in this embodiment to be in the range of 20 to 30 degrees from the vertical.

The implant energy is chosen to be in the range of 1 keV to 10 keV. In one embodiment the implant energy is chosen to be between 1 keV and 6 keV, preferably at 2 keV.

The gate leakage reduction species dosage in this embodiment is chosen to fall in the range from 1e14 to 1e15. In a preferred embodiment the dosage is chosen to be between 2e14 and 8e14, preferably at 6e14. The invention applies to the reduction of gate leakage in both PMOS and NMOS devices.

In the case of an SRAM device, the present invention has the benefit of reducing data retention fails, which can be ascribed to two major fail modes: storage node-to-storage node (SN-SN) leakage due to gate leakage, and storage node-to-Nwell (SN-NW) leakage due to high n-well leakage. The above leakages are typically caused by implant damage resulting in an amorphous looking silicon in the source and drain regions. The other contributing factor to SN-SN and SN-NW leakage is high gate area and perimeter, which tend to increase gate leakage.

As mentioned above, the gate edge defects in the gate oxide will cause leakage if there is a complete line of defects from bottom of the gate to the top of the n-channel. By introducing gate leakage reduction species such as a nitrogen pockets along edges of the gate as shown in FIGS. 3 and 4, the defect line is broken up, thereby reducing gate leakage. In particular, by implanting the nitrogen pockets at the optimum location by carefully controlling the implantation energy, and using the optimum dose, gate leakage median and outliers are reduced.

This also allows the quiescent power supply current IDDQ in the MOS transistors of the SRAM to be reduced since gate leakage is the dominant IDDQ component at room temperature.

Since data retention fails are reduced, the present invention allows Vdd to be reduced for low power operation.

The invention also reduces gate leakage without having to resort to increased gate oxide thickness, which would otherwise affect all devices in the technology. This has the benefit of allowing late technology improvements without significant reliability re-qualification.

While the above description was directed specifically to reduction in gate leakage of MOS devices used in SRAM memory, thereby reducing data retention fails and allowing low Vdd operation without increasing gate oxide thickness, it will be appreciated that the invention is not so limited. The method of reducing gate leakage by implanting nitrogen pockets into the gate oxide along the edge of the MOS gate can be applied to any MOS devices to reduce charge leakage.

What is claimed is:

1. A method of reducing gate leakage in a MOS transistor, comprising implanting a gate oxide leakage reduction species into the gate oxide along the edges of the gate at an implant angle of 20 to 30 degrees.

2. A method of claim 1, wherein the gate oxide leakage reduction species comprises nitrogen, the implant defining nitrogen pockets along edges of the gate.

3. A method of claim 1, wherein the angled implants are implanted at energies ranging from 1 keV to 10 keV.

4. A method of claim 3, wherein the angled implants are implanted at energies ranging from 1 keV to 6 keV.

5. A method of claim 4, wherein the angled implants are implanted at an energy of 2 keV.

6. A method of claim 1, wherein the angled implants are implanted at a dosage ranging from 1e14 to 1e15.

7. A method of claim 6, wherein the angled implants are implanted at a dosage ranging from 2e14 to 8e14.

8. A method of claim 7, wherein the angled implants are implanted at a dosage of 6e14.

9. A method of reducing gate leakage in a MOS transistor, comprising implanting nitrogen in the gate oxide along gate edges to replace lost nitrogen that was included in the gate oxide during growth.

10. A method of claim 9, wherein the nitrogen implants are implanted at energies ranging from 1 keV to 10 keV.

11. A method of claim 10, wherein the nitrogen implants are implanted at energies ranging from 1 keV to 6 keV.

12. A method of claim 11, wherein the nitrogen implants are implanted at an energy of 2 keV.

13. A method of claim 9, wherein the nitrogen implants are implanted at a dosage ranging from 1e14 to 1e15.

14. A method of claim 13, wherein the nitrogen implants are implanted at a dosage ranging from 2e14 to 8e14.

15. A method of claim 14, wherein the nitrogen implants are implanted at a dosage of 6e14.

16. A MOS transistor that includes a gate oxide and gate located over the gate oxide, comprising
a gate oxide leakage reduction species configured to define pockets extending along edges of the gate.

17. A MOS transistor of claim 16, wherein the gate oxide leakage reduction species pockets comprise nitrogen pockets.

18. A MOS transistor of claim 16, wherein the dosage of the gate oxide leakage reduction species ranges from 1e14 to 1e15.

19. A MOS transistor of claim 18, wherein the dosage of the gate oxide leakage reduction species ranges from 2e14 to 8e14.

20. A MOS transistor of claim 19, wherein the dosage of the gate oxide leakage reduction species is 6e14.
